(19) United States
(12) Patent Application Publication
(10) Pub. No.: US 2025/0176302 A1
(43) Pub. Date: May 29, 2025

(54) APPARATUS, SYSTEM, AND MOVABLE BODY

(71) Applicant: CANON KABUSHIKI KAISHA, Tokyo (JP)

(72) Inventors: DAIKI SHIRAHIGE, Kanagawa (JP); YUSUKE ONUKI, Kanagawa (JP)

(21) Appl. No.: 18/951,323

(22) Filed: Nov. 18, 2024

(30) Foreign Application Priority Data
Nov. 28, 2023 (JP) 2023-200344

(51) Int. Cl. H01L 27/146

(52) U.S. Cl. CPC H10F 39/811; H10F 39/8037; H10F 39/8063

(57) ABSTRACT

An apparatus includes a plurality of pixels arranged in an array, wherein each of the plurality of pixels includes a plurality of conversion units that share a microlens, wherein the plurality of conversion units of a first pixel of the plurality of pixels is separated in a first direction, wherein the plurality of conversion units of a second pixel of the plurality of pixels is separated in a second direction, wherein a floating diffusion is arranged in one of a position between columns and a position between rows of the conversion units included in the plurality of pixels, and wherein a well contact is arranged in the other of the position between columns and the position between rows of the conversion units included in the plurality of pixels.

### BACKGROUND

### Technical Field

The aspect of the embodiments relates to an apparatus, a system, and a movable body.

### Description of the Related Art

There has been an image sensor including a plurality of photoelectric conversion elements in each pixel to perform image plane phase difference autofocus (AF). As discussed in Japanese Patent Application Laid-Open No. 2023-27686, to improve AF performance, an arrangement direction (array direction) of photoelectric conversion elements in a pixel is sometimes made different for some pixels from the arrangement direction of the photoelectric conversion elements therein for other pixels.

Japanese Patent Application Laid-Open No. 2023-27686 does not discuss an arrangement of a well contact in the image sensor, and does not clearly indicate a desirable arrangement of the well contact that takes into account an influence of the well contact exerted on pixel characteristics.

### SUMMARY

According to an aspect of the embodiments, an apparatus includes a plurality of pixels arranged in an array, wherein each of the plurality of pixels includes a plurality of conversion units that share a microlens, wherein the plurality of conversion units of a first pixel of the plurality of pixels is separated in a first direction, wherein the plurality of conversion units of a second pixel of the plurality of pixels is separated in a second direction, wherein a floating diffusion is arranged in one of a position between columns and a position between rows of the conversion units included in the plurality of pixels, and wherein a well contact is arranged in the other of the position between columns and the position between rows of the conversion units included in the plurality of pixels.

Further features of the disclosure will become apparent from the following description of exemplary embodiments with reference to the attached drawings.

### BRIEF DESCRIPTION OF THE DRAWINGS

FIG. 1 is a schematic diagram illustrating a sensor array of a photoelectric conversion apparatus according to a first exemplary embodiment.

FIGS. 2A and 2B are plan views of a unit cell of the photoelectric conversion apparatus according to the first exemplary embodiment.

FIGS. 3A, 3B, and 3C are diagrams illustrating variations of the sensor array of the photoelectric conversion apparatus according to the first exemplary embodiment.

FIGS. 4A, 4B, 4C, 4D, and 4E are pixel cross-sectional views of the unit cell of the photoelectric conversion apparatus according to the first exemplary embodiment.

FIGS. 5A, 5B, 5C, 5D, and 5E are pixel cross-sectional views of the unit cell of the photoelectric conversion apparatus according to the first exemplary embodiment.

FIG. 6 is a pixel plan view of the unit cell of the photoelectric conversion apparatus according to the first exemplary embodiment.

FIG. 7 is a pixel plan view of a unit cell of a photoelectric conversion apparatus according to a second exemplary embodiment.

FIG. 8 is a pixel plan view of a unit cell of a photoelectric conversion apparatus according to a third exemplary embodiment.

FIG. 9 is a pixel plan view of a unit cell of a photoelectric conversion apparatus according to a fourth exemplary embodiment.

FIGS. 10A, 10B, 10C, and 10D are each a pixel plan view of a unit cell of a photoelectric conversion apparatus according to a fifth exemplary embodiment.

FIGS. 11A, 11B, 11C, and 11D are each a pixel plan view of a unit cell of a photoelectric conversion apparatus according to a fifth exemplary embodiment.

FIG. 12 is a functional block diagram of a photoelectric conversion system according to a sixth exemplary embodiment.

FIGS. 13A and 13B are functional block diagrams of a photoelectric conversion system according to a seventh exemplary embodiment.

FIG. 14 is a functional block diagram of a photoelectric conversion system according to an eighth exemplary embodiment.

FIG. 15 is a functional block diagram of a photoelectric conversion system according to a ninth exemplary embodiment.

FIGS. 16A and 16B are functional block diagrams of a photoelectric conversion system according to a tenth exemplary embodiment.

FIG. 17 is a functional block diagram of a photoelectric conversion system according to an eleventh exemplary embodiment.

### DESCRIPTION OF THE EMBODIMENTS

In each exemplary embodiment described below, an imaging apparatus will be mainly described as an example of a photoelectric conversion apparatus. However, the photoelectric conversion apparatus in each exemplary embodiment is not limited to the imaging apparatus, and each exemplary embodiment can be applied to another example of the photoelectric conversion apparatus. Examples of the photoelectric conversion apparatus include a distance measurement apparatus (apparatus for distance measurement that uses focus detection or Time Of Flight (TOF)), and a photometric apparatus (apparatus for measurement of an incident light amount).

Hereinafter, exemplary embodiments of the disclosure will be described in detail with reference to the drawings. In the following description, terms (e.g., “up”, “down”, “right”, “left”, and other terms including these terms) indicating specific directions and positions are used as necessary. These terms are used to facilitate understanding of the exemplary embodiments to be described with reference to the drawings. The technical scope of the aspect of the embodiments is not to be limited by the meanings of these terms.

In the present specification, a planar view refers to a view from a direction vertical to a light incidence surface of a semiconductor layer. A cross-sectional view refers to viewing a cross section vertical to the light incidence surface of the semiconductor layer. In a case where the light incidence surface of the semiconductor layer is a rough surface when viewed microscopically, the planar view is defined based on a light incidence surface of a semiconductor layer when viewed macroscopically.

The semiconductor layer has a first surface, and a second surface being a surface on the opposite side of the first surface and a surface that light enters.

In the present specification, a depth direction refers to a direction extending from the first surface to the second surface of the semiconductor layer. On the first surface of the semiconductor layer, a transistor is disposed, and wiring layers are stacked. Hereinafter, the “first surface” may be sometimes referred to as a “front surface”, and the “second surface” may be sometimes referred to as a “rear surface”. The “depth” of a certain point or a certain region in the semiconductor layer means a distance of the point or the region from the first surface (front surface). When a point (or region) Z1 with a distance (depth) dl from the first surface and a point (or region) Z2 with a distance (depth) d2 from the first surface exist, and d1>d2 is satisfied, such a state is sometimes expressed as a state where “the point Z1 is deeper than the point Z2” or “the point Z2 is shallower than the point Z1”. In addition, when a point (or region) Z3 with a distance (depth) d3 from the first surface exists, and d1>d3>d2 is satisfied, such a state is sometimes expressed as a state where “the point Z3 exists between the depths of the points Z1 and Z2” or “the point Z3 exists between the points Z1 and Z2 in the depth direction”.

Conductivity types of semiconductor regions and wells, and dopants to be implanted, which will be described below in the following exemplary embodiments, are mere examples. The conductivity types and the dopants are not limited to those described in the exemplary embodiments. The conductivity types and the dopants can be appropriately changed from those described in the exemplary embodiments, and the potentials of semiconductor regions and wells are appropriately changed in accordance with the change.

A conductivity type of a transistor to be described in the following exemplary embodiments is a mere example, and the conductivity type is not limited to the conductivity type described in the exemplary embodiments. The conductivity type can be appropriately changed from the conductivity type described in the exemplary embodiments, and potentials of a gate, a source, and a drain of the transistor are appropriately changed in accordance with the change.

For example, as for a transistor to be operated as a switch, it is sufficient that a low level and a high level of a potential to be supplied to a gate are made reverse to those described in the exemplary embodiments, in accordance with the change of a conductivity type. In addition, the conductivity type of a semiconductor region to be described in the following exemplary embodiments is a mere example, and the conductivity type is not limited to the conductivity type described in the exemplary embodiments. The conductivity type can be appropriately changed from the conductivity type described in the exemplary embodiments, and the potential of the semiconductor region is appropriately changed in accordance with the change.

In the following exemplary embodiments, connection between elements of circuits will be sometimes described. In this case, even when another element is interposed between elements to be observed, unless otherwise noted, the elements to be observed are treated as being connected. For example, suppose that an element A is connected to one node of a capacitative element C having a plurality of nodes, and an element B is connected to the other node. In such a case, unless otherwise noted, the elements A and B are treated as being connected.

A metal member, such as a wire and a pad, described in the present specification may be made of a single-component metal of one certain element, or may be a mixture (alloy). For example, a wire to be described as a copper wire may be made of a single component of copper, or may be made mainly of copper and further containing other components. In addition, for example, a pad to be connected with an external terminal may be made of a single component of aluminum, or may be made mainly of aluminum and further containing other components. The copper wire and the aluminum pad described here are examples, and can be changed to various other types of metal. In addition, the wire and the pad described here are examples of metal members used in a photoelectric conversion apparatus, and the above-described various metal configurations can also be applied to other metal members.

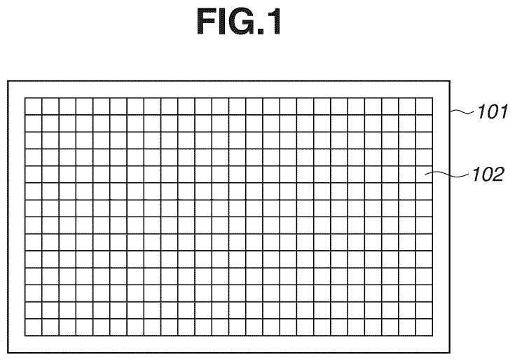

A photoelectric conversion apparatus according to a first exemplary embodiment will be described with reference to FIGS. 1 to 6.

FIG. 1 is a schematic top view of a photoelectric conversion apparatus 101 according to an exemplary embodiment of the disclosure. The photoelectric conversion apparatus 101 according to the present exemplary embodiment is what is called a back-illuminated type photoelectric conversion apparatus, and includes a sensor substrate including a semiconductor layer including a plurality of pixels 102 arranged in an array having a plurality of rows and a plurality of columns, and a wiring structure stacked on the front surface of the semiconductor layer. The photoelectric conversion apparatus 101 may be a stacked type photoelectric conversion apparatus including a sensor substrate, and a circuit substrate that processes a signal output from the sensor substrate, which are stacked and electrically connected. Alternatively, the photoelectric conversion apparatus 101 may be a non-stacked type photoelectric conversion apparatus in which components included in a sensor substrate and components included in a circuit substrate are arranged in a common semiconductor layer.

The pixels 102 include at least two types of pixels of a first pixel 102 and a second pixel 102. A pixel 102 refers to a minimum unit of a circuit that is repeatedly arranged to form an image. The pixel 102 includes at least a photoelectric conversion unit and a pixel circuit. The pixel circuit may include at least one of a transfer transistor, a floating diffusion (hereinafter, FD), a reset transistor, an amplifying transistor, a capacity connection transistor, or a selection transistor. Typically, a selection transistor and a group of elements connected to a signal line via the selection transistor constitute a pixel circuit. In other words, the selection transistor can be an outer edge of the pixel circuit.

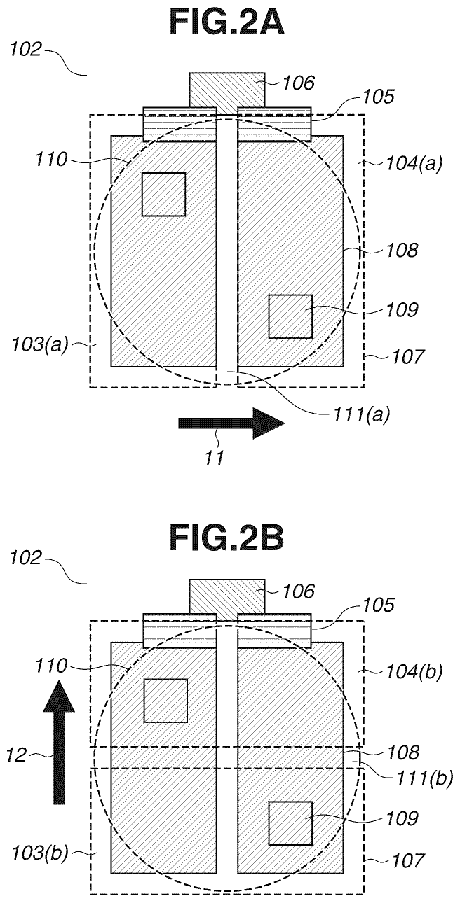

FIGS. 2A and 2B are plan views respectively illustrating the first pixel 102 and the second pixel 102. FIGS. 2A and 2B are plan views each illustrating elements arranged in a corresponding pixel 102 as viewed from the front surface side of a semiconductor substrate. For a descriptive purpose, an element overlapping the elements is also indicated by a broken line.

The first pixel 102 illustrated in FIGS. 2A and 2B includes a rear surface side N-type semiconductor region 107 that photoelectrically-converts incident light, and a front surface side N-type semiconductor region 108 that accumulates electrons generated by photoelectric conversion. The rear surface side N-type semiconductor region 107 and the front surface side N-type semiconductor region 108 are connected by an N-type connection region 109 including an N-type semiconductor region. Charges photoelectrically converted by the rear surface side N-type semiconductor region 107 move to the front surface side N-type semiconductor region 108 via the N-type connection region 109. Hereinafter, an “N-type semiconductor region” will be simply referred to as an “N-type region”.

Here, rear surface side N-type regions 107 are separated by first separation portions 111(a) and 111(b) into a first photoelectric conversion unit 103(a) and a second photoelectric conversion unit 104(a), and into a first photoelectric conversion unit 103(b) and a second photoelectric conversion unit 104(b), respectively. The first photoelectric conversion unit 103(a) and the second photoelectric conversion unit 104(a) share one microlens 110, and the first photoelectric conversion unit 103(b) and the second photoelectric conversion unit 104(b) share one microlens 110.

In a pixel configuration in which a plurality of photoelectric conversion units (photoelectric conversion elements) is arranged for one microlens for a purpose of image plane phase difference autofocus (AF), an easy-to-detect subject pattern varies depending on an arrangement direction of the photoelectric conversion elements. For example, when the plurality of photoelectric conversion elements is arranged in a column direction, while it becomes easier to put a focus on a subject with vertical stripe contrast, it becomes difficult to put a focus on a subject with horizontal stripe contrast. Accordingly, by arranging pixels in which the photoelectric conversion elements are arranged in a direction (e.g., row direction) different from the column direction, a sensor that can easily put a focus on a larger number of subject patterns is implemented.

FIG. 2A illustrates a pixel in which the first separation portion 111(a) having a longer side direction in a direction intersecting a first direction (direction 11) is arranged in such a manner that the first photoelectric conversion unit 103(a) and the second photoelectric conversion unit 104(a) are arranged in the first direction. By employing such an arrangement, it becomes easier to put a focus on the subject with vertical stripe contrast.

On the other hand, FIG. 2B illustrates a pixel in which the first separation portion 111(b) having a longer side direction in a direction intersecting a second direction (direction 12) different from the first direction is arranged in such a manner that the first photoelectric conversion unit 103(b) and the second photoelectric conversion unit 104(b) are arranged in the second direction. In the case of such an arrangement, it becomes easier to put a focus on the subject with horizontal stripe contrast.

Here, while the arrangement direction of the separated rear surface side N-type regions 107 varies between the pixel 102 in FIG. 2A and the pixel 102 in FIG. 2B, an arrangement direction of separated front surface side N-type regions 108 remains the same in both the pixel 102 in FIG. 2A and the pixel 102 in FIG. 2B. By employing such a configuration, it is possible to uniformize not only the arrangement of the front surface side N-type regions 108 but also the arrangement of a transfer gate 105 of a transfer transistor and an FD 106 in both the pixel 102 in FIG. 2A and the pixel 102 in FIG. 2B. By uniformizing the arrangement of the transfer gate 105 and the FD 106 among the pixels 102, it is possible to suppress a transfer characteristic difference attributed to an ion implantation variation in manufacturing. Because a wiring layer can be created with a fixed repetition unit, design of a transistor and a wire in a pixel portion becomes easier.

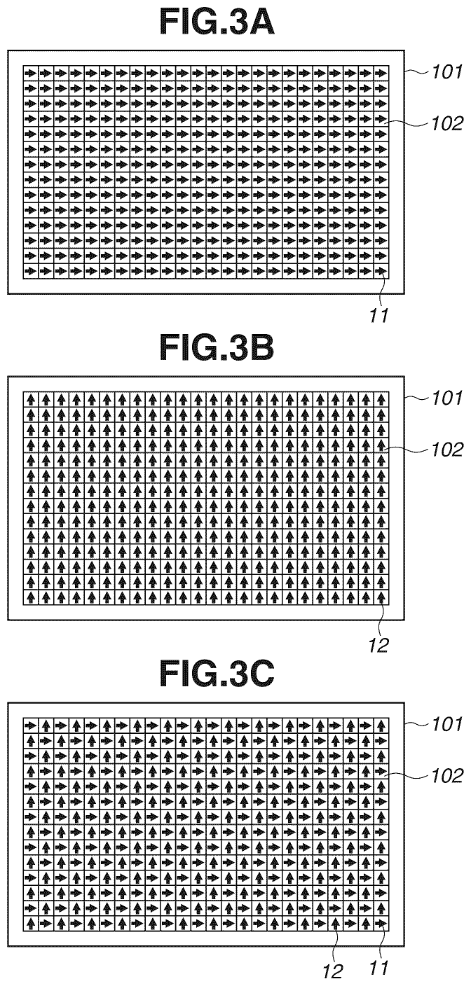

FIGS. 3A, 3B, and 3C illustrate arrangement examples of the pixels 102 of a plurality of types, and arrangement directions (array directions) of the pixels 102 are different from each other on the rear surface side N-type regions 107. FIGS. 3A, 3B, and 3C each illustrate the arrangement example of the pixels 102 in the photoelectric conversion apparatus 101, and an arrow direction indicates the arrangement direction of the rear surface side N-type regions 107.

FIG. 3A illustrates the photoelectric conversion apparatus 101 in which a plurality of pixels 102, each including two rear surface side N-type regions 107 arranged in the direction 11 as illustrated in FIG. 2A, is arranged. FIG. 3B illustrates the photoelectric conversion apparatus 101 in which a plurality of pixels 102, each including two rear surface side N-type regions 107 arranged in the direction 12 as illustrated in FIG. 2B, is arranged. FIG. 3C illustrates an example of the photoelectric conversion apparatus 101 in which the plurality of pixels 102 each including two rear surface side N-type regions 107 arranged in the direction 11 and the plurality of pixels 102 each including two rear surface side N-type regions 107 arranged in the direction 12 are arranged in a checkerboard pattern.

As described above, the direction of stripe of contrast on which a focus is easily put of a subject is determined depending on the arrangement direction of the rear surface side N-type regions 107. Thus, in the photoelectric conversion apparatus 101 in FIG. 3A, it becomes possible to execute AF on a subject with vertical stripe contrast at high speed and with high accuracy, and in the photoelectric conversion apparatus 101 in FIG. 3B, it becomes possible to execute AF on a subject with horizontal stripe contrast at high speed and with high accuracy. In the photoelectric conversion apparatus 101 in FIG. 3C in which a plurality of types of pixels 102 different from each other in the arrangement direction of the rear surface side N-type regions 107 are mixed, it becomes possible to execute AF on the subjects with vertical stripe contrast and with horizontal stripe contrast at high speed and with high accuracy.

The arrangement of pixels 102 is not limited to this, and for example, blocks each including a plurality of pixels 102 each including the rear surface side N-type regions 107 arranged in the direction 11, and blocks each including a plurality of pixels 102 each including the rear surface side N-type regions 107 arranged in the direction 12 may be arranged in a checkerboard pattern.

In the above description, the first direction and the second direction in which the plurality of rear surface side N-type regions 107 is arranged are orthogonal to each other. Nevertheless, a configuration in which the plurality of rear surface side N-type regions 107 is arranged in such a manner that the first direction and the second direction intersect with each other at an angle other than 90°, such as 45° or 30°, may be employed.

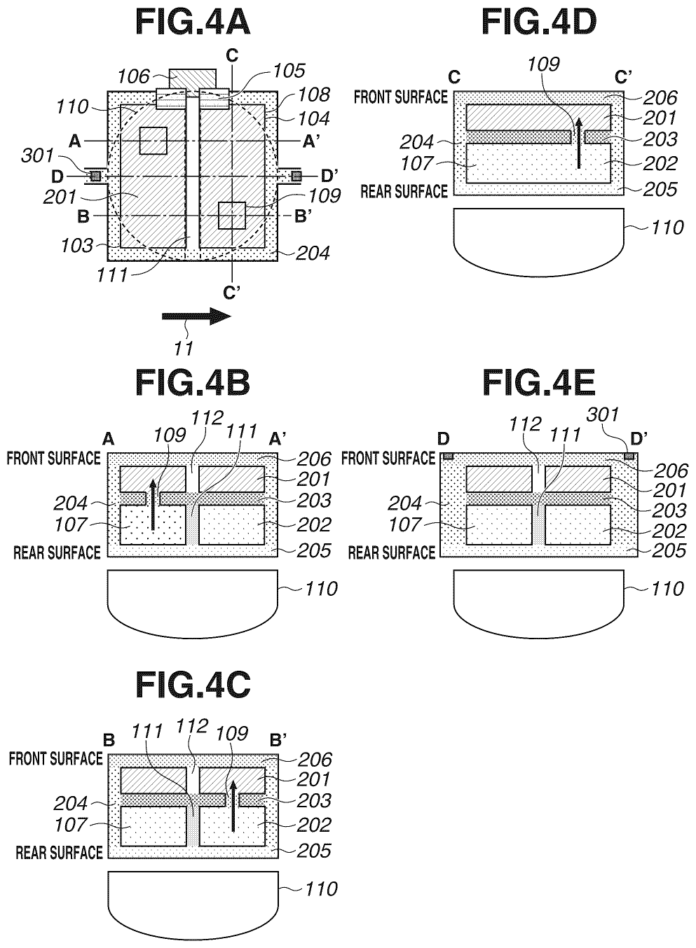

FIG. 4A is a plan view of the first pixel 102 according to the present exemplary embodiment. FIGS. 4B, 4C, 4D, and 4E are schematic diagrams of four cross sections of the first pixel 102 according to the present exemplary embodiment. A cross section taken along A-A′ illustrated in FIG. 4A corresponds to FIG. 4B, and a cross section taken along B-B′ corresponds to FIG. 4C. In a similar manner, a cross section taken along C-C′ corresponds to FIG. 4D, and a cross section taken along D-D′ corresponds to FIG. 4E. In FIGS. 4A, 4B, 4C, 4D, and 4E, the rear surface side N-type region 107 and the front surface side N-type region 108 will be referred to as a second semiconductor region 202 and a first semiconductor region 201, respectively, as appropriate.

As illustrated in FIG. 4B, in the cross section taken along A-A′ in FIG. 4A, the pixel 102 includes a fifth semiconductor region 205, the second semiconductor region 202, the first separation portion 111 (111(a) or 111(b)), a third semiconductor region 203, a fourth semiconductor region 204, the first semiconductor region 201, and a sixth semiconductor region 206 in order from the rear surface side.

Light having passed through the microlens 110 enters the pixel 102 from the rear surface side, and is photoelectrically-converted in a region including an N-type (first conductivity type) second semiconductor region 202 in the pixel 102. An electron generated by the photoelectric conversion moves to an N-type first semiconductor region 201 through the N-type connection region 109 along a potential gradient, and is accumulated therein. An N-type impurity concentration of the first semiconductor region 201 is higher than an N-type impurity concentration of the second semiconductor region 202. A P-type (second conductivity type) third semiconductor region 203 is arranged between the first semiconductor region 201 and the second semiconductor region 202 in a depth direction. A moving path to be used when a signal charge moves from the second semiconductor region 202 to the first semiconductor region 201 is thereby limited to the N-type connection region 109. With this configuration, even in a case where the arrangement direction of the plurality of rear surface side N-type regions 107 and the arrangement direction of the plurality of front surface side N-type regions 108 are different, it is possible to move charges to a desired first semiconductor region 201.

At a boundary portion where one pixel 102 neighbors another pixel 102, for a purpose of preventing charge crosstalk with the neighboring other pixel 102, the P-type fourth semiconductor region 204 is arranged. In addition, for a purpose of suppressing a dark current, the P-type fifth semiconductor region 205 and the P-type sixth semiconductor region 206 are arranged near the rear surface and near the front surface of the semiconductor layer, respectively.

The first separation portion 111 is arranged between the first photoelectric conversion unit 103 (103(a), 103(b)) and the second photoelectric conversion unit 104 (104(a), 104(b)) arranged in one pixel 102. The first separation portion 111 that prevents charge crosstalk between an N-type first photoelectric conversion unit 103 and an N-type second photoelectric conversion unit 104 may be a P-type semiconductor region, or may be a separation portion having a trench structure. By employing the separation portion having a trench structure, a configuration that also prevents optical crosstalk is obtained.

In a similar manner, the first semiconductor region 201 is separated by a second separation portion 112 in such a manner that separated regions respectively correspond to the first photoelectric conversion unit 103 and the second photoelectric conversion unit 104. In the pixel 102 illustrated in FIGS. 4A, 4B, 4C, 4D, and 4E, directions in which the first separation portion 111 and the second separation portion 112 extend are identical to each other.

Similarly, in the cross section taken along B-B′ in FIG. 4A that is illustrated in FIG. 4C and the cross section taken along C-C′ in FIG. 4A that is illustrated in FIG. 4D, electrons generated in the second semiconductor region 202 are accumulated in the first semiconductor region 201 through the N-type connection region 109.

As illustrated in FIG. 4E, the cross section taken along D-D′ in FIG. 4A indicates a configuration in which well contacts 301 for supplying potentials to wells are arranged between the pixel 102 and left and right neighboring pixels 102. Here, the well refers to a region to be formed by injecting an impurity to a transistor formation point, and the well contact 301 supplies voltage to the fourth semiconductor region 204 via the sixth semiconductor region 206. Because the well contact 301 can be a generation source of a dark current, in one embodiment, the well contact 301 is formed at a distance from the first semiconductor region 201 in which signal charges are accumulated. Specifically, it is possible to suppress the dark current by arranging the well contact 301 at a position that is closer to the substrate front surface and is shallower than a position of the first semiconductor region 201 that is close to the substrate rear surface, i.e., not arranging the well contact 301 and the first semiconductor region 201 at the same position in the depth direction.

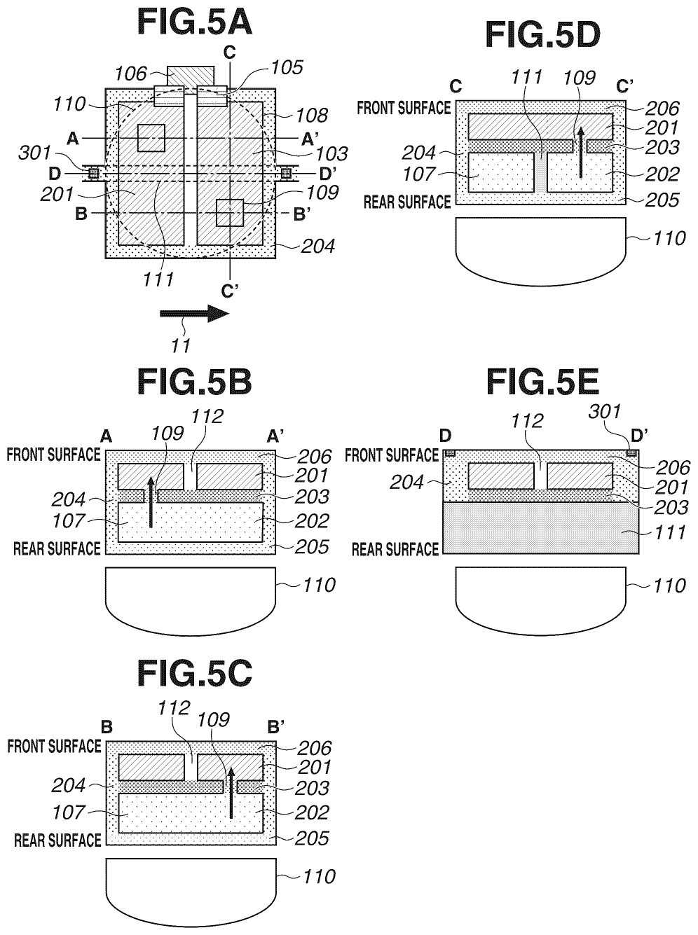

By forming a P-type semiconductor region around the well contact 301, it is possible to suppress the dark current by recombining the generated dark current. To have contact with a semiconductor substrate (semiconductor layer), a high concentration P-type semiconductor region is formed around the well contact 301. To further enhance a dark current suppression effect, the well contact 301 may partially or entirely overlap the sixth semiconductor region 206 in a planar view. Moreover, the well contact 301 may be arranged in a region where the well contact 301 partially overlaps the sixth semiconductor region 206 in the depth direction. FIG. 5A is a plan view of the second pixel 102 according to the present exemplary embodiment. FIGS. 5B, 5C, 5D, and 5E are schematic diagrams illustrating four cross sections of the second pixel 102 according to the present exemplary embodiment. A cross section taken along A-A′ illustrated in FIG. 5A corresponds to FIG. 5B, a cross section taken along B-B′ corresponds to FIG. 5C, a cross section taken along C-C′ corresponds to FIG. 5D, and a cross section taken along D-D′ corresponds to FIG. 5E. In FIGS. 5A, 5B, 5C, 5D, and 5E, the rear surface side N-type region 107 and the front surface side N-type region 108 will be referred to as the second semiconductor region 202 and the first semiconductor region 201, respectively, as appropriate. The description of a configuration identical to the pixel configuration described with reference to FIGS. 4A, 4B, 4C, 4D, and 4E will be omitted, and a difference of the second pixel 102 from the first pixel 102 illustrated in FIGS. 4A, 4B, 4C, 4D, and 4E will be described.

The second pixel 102 illustrated in FIGS. 5A, 5B, 5C, 5D, and 5E differs from the first pixel 102 illustrated in FIGS. 4A, 4B, 4C, 4D, and 4E in the arrangement direction (array direction) of the rear surface side N-type regions 107. More specifically, the first pixel 102 illustrated in FIGS. 4A, 4B, 4C, 4D, and 4E and the second pixel 102 illustrated in FIGS. 5A, 5B, 5C, 5D, and 5E differ in the direction in which the first separation portion 111 extends.

As illustrated in FIGS. 5B and 5C, in the cross section taken along A-A′ and the cross section taken along B-B′ in FIG. 5A, an electron generated by photoelectric conversion in the second semiconductor region 202 moves to the first semiconductor region 201 through the N-type connection region 109, and is accumulated. The first semiconductor region 201 is separated into two portions by the second separation portion 112.

On the other hand, as illustrated in FIG. 5D, in the cross section taken along C-C′ in FIG. 5A, the second semiconductor region 202 is separated into two portions by the first separation portion 111. More specifically, in the second pixel 102 illustrated in FIGS. 5A, 5B, 5C, 5D, and 5E, in a planar view with respect to a semiconductor layer, the first separation portion 111 and the second separation portion 112 differ in extending direction, and the first separation portion 111 of the first pixel 102 and the first separation portion 111 of the second pixel 102 differ in extending direction.

By changing the arrangement direction of the rear surface side N-type regions 107, it is possible to change a direction in which phase difference detection can be performed when performing image plane phase difference AF. Because the phase difference detection direction can be changed without changing the arrangement direction of the front surface side N-type regions 108, it is possible to uniformize the arrangement of the transfer gate 105 and the FD 106 among the pixels 102. Accordingly, also in a plurality of pixels 102 different from each other in the arrangement direction of the rear surface side N-type regions 107, it is possible to suppress the transfer characteristic difference attributed to an ion implantation variation in manufacturing. Because a wiring layer can be created with a fixed repetition unit, the design of a transistor and a wire in a pixel portion becomes easier.

As illustrated in FIG. 5E the cross section taken along D-D′ in FIG. 5A indicates a configuration in which the well contacts 301 for supplying potentials to wells are arranged between the pixel 102 and left and right neighboring pixels 102.

Because the well contact 301 can be a generation source of a dark current, in one embodiment, the well contact 301 is formed at a distance from the first semiconductor region 201 in which signal charges are accumulated. Specifically, it is possible to suppress the dark current by arranging the well contact 301 at a position that is closer to the substrate front surface and is shallower than a position of the first semiconductor region 201 that is close to the substrate rear surface, i.e., not arranging the well contact 301 and the first semiconductor region 201 at the same position in the depth direction.

By forming a P-type semiconductor region around the well contact 301, it is possible to suppress the dark current by recombining the generated dark current. To have contact with a semiconductor substrate (semiconductor layer), a high concentration P-type semiconductor region is formed around the well contact 301. To further enhance a dark current suppression effect, the well contact 301 may partially or entirely overlap the sixth semiconductor region 206 in a planar view. Moreover, the well contact 301 may be arranged in a region where the well contact 301 partially overlaps the sixth semiconductor region 206 in the depth direction.

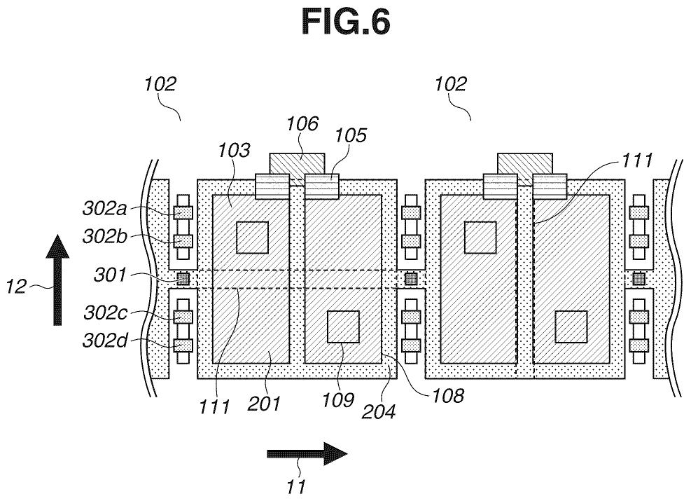

FIG. 6 is a pixel plan view of the first pixel 102 and the second pixel 102 according to the present exemplary embodiment.

The arrangement of a plurality of well contacts 301 in the photoelectric conversion apparatus according to the present exemplary embodiment that includes the first pixel 102 and the second pixel 102 will be described with reference to FIG. 6.

FIG. 6 illustrates the first pixel 102 and the second pixel 102 in one pixel row among the plurality of pixels 102 arranged in the photoelectric conversion apparatus in an array including a plurality of rows and a plurality of columns.

As illustrated in FIG. 6, in a configuration in which the FD 106 is arranged in an upper part of the pixel 102 in a planar view, the FD 106 is arranged between rows of the photoelectric conversion units included in neighboring pixels 102, and a pixel transistor 302 is arranged between columns of the photoelectric conversion units included in the neighboring pixels 102. The pixel transistor 302 is a selection transistor for reading a charge from a pixel 102, for example.

To give a well potential to wells of the plurality of pixels 102 arranged in an array in the photoelectric conversion apparatus, the well contact 301 is arranged between the photoelectric conversion units included in the pixels 102. By the well contact 301 being arranged in the pixel array, a reference well potential is given to the P-type fourth semiconductor region 204 in the pixel 102.

In the photoelectric conversion apparatus according to the present exemplary embodiment, from a viewpoint of layout efficiency, the well contact 301 is arranged not between rows of the photoelectric conversion units included in the neighboring pixels 102 where the FD 106 is arranged, but between columns of the photoelectric conversion units included in the neighboring pixels 102. With this configuration, the well contact 301 does not interfere with the FD 106 and the pixel transistor 302 arranged around the well contact 301.

An example in which the FD 106 is arranged between the rows of the photoelectric conversion units included in the pixels 102, and the well contact 301 is arranged between the columns of the photoelectric conversion units included in the pixels 102 has been described with reference to FIG. 6. Nevertheless, in a structure in which the FD 106 is arranged between the columns of the photoelectric conversion units included in the neighboring pixels 102, and the well contact 301 is arranged between the rows of the photoelectric conversion units included in neighboring pixels 102, a similar layout efficiency improvement effect can be obtained.

As illustrated in FIG. 6, the well contact 301 may be arranged at a position sandwiched between two transistors of a plurality of pixel transistors 302 arranged in the second direction (direction 12, column direction). Considering that the well contact 301 is arranged between the columns of the photoelectric conversion units included in neighboring pixels 102, and a well potential is supplied to each of the pixels 102, in one embodiment, the well contact 301 is arranged near the same position as the center of the pixel 102 in the direction 12. In other words, in a case where two line segments extending in the first direction 11 (direction 11, row direction) are arranged in such a manner that an area of the pixel 102 is equally divided into three, the well contact 301 is arranged in a region sandwiched between the two line segments.

From the viewpoint of layout efficiency, in one embodiment, the well contact 301 is also arranged near the same position as the center of the pixel 102 in the direction 12.

In a case where the well contact 301 is arranged in an upper part or a lower part of the pixel 102 with regard to the second direction 12, a layout symmetric property with the pixel transistors 302 adjacently arranged in the direction 12 is impaired. On the other hand, in a case where the well contact 301 is arranged near the center of the pixel 102 with regard to the direction 12, the layout symmetric property is maintained when the pixel transistors 302 are arranged above and below the well contact 301. With this configuration, it is possible to suppress a characteristic variation among the plurality of pixel transistors 302.

For example, as illustrated in FIG. 6, the well contact 301 may be arranged near the center of the pixel 102 with regard to the direction 12, and the pixel transistors 302 of the same type may be arranged in such a manner as to sandwich the well contact 301 with regard to the direction 12. Here, the pixel transistors 302 of the same type means that functions of the transistors are the same. For example, the well contact 301 is arranged between a first selection transistor for reading charges of the first pixel 102 and a second selection transistor for reading charges of the second pixel 102.

Because the first separation portion 111 is supplied with a potential from the left well contact 301 in the left pixel 102 and near the left pixel 102 in FIG. 6, in one embodiment, the first separation portion 111 and the left well contact 301 are arranged closely to each other. In one embodiment, a line segment passing through the center of the first separation portion 111 and a part of the well contact 301 overlap in a planar view, but the arrangement is not limited to such an arrangement, and a certain degree of deviation is allowed from a viewpoint of potential supply. Specifically, the well contact 301 may be separated from the line segment passing through the center of the first separation portion 111 as long as a distance therebetween is a distance nearly equal to a width of the separation portion between the pixels 102. For example, in a case where a width of the fourth semiconductor region 204 is a 1-μm width, the well contact 301 may be separated from the first separation portion 111 by 1 μm. In one embodiment, at least a part of the well contact 301 is arranged in a region within 1 μm with regard to the direction 12 from an extended line obtained by extending the first separation portion 111, and in another embodiment, the line segment passing through the center of the first separation portion 111 and a line segment passing through the center of the well contact 301 overlap.

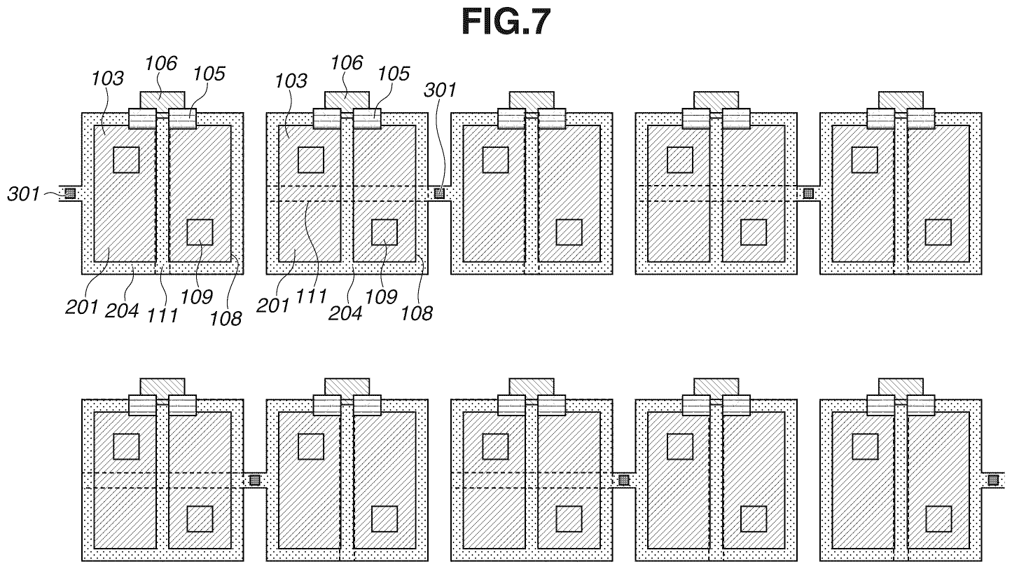

A second exemplary embodiment of the disclosure will be described with reference to FIG. 7. A photoelectric conversion apparatus to be described in the second exemplary embodiment differs in arrangement of the well contact 301 as compared with the photoelectric conversion apparatus described in the first exemplary embodiment.

As the first exemplary embodiment, a configuration in which the well contacts 301 are arranged between all pixel columns has been described. By arranging the well contacts 301 between all the pixel columns, stable potential supply can be expected, but there is a concern that a dark current attributed to the well contact 301 increases. In contrast thereto, in the present exemplary embodiment, the well contacts 301 are alternately arranged in every other pixel column. In a case where the well contacts 301 are alternately arranged in every other pixel column, because the number of the well contacts 301 arranged in a pixel array can be reduced, it is possible to suppress the dark current attributed to the well contact 301.

As illustrated in FIG. 7, a column in which the well contact 301 is arranged and a column in which the well contact 301 is not arranged may vary among rows. The arrangement of the well contact 301 is not limited thereto. With this configuration, it is possible to further reduce the number of the well contacts 301, and the dark current is suppressed.

In the arrangement of the well contact 301 as described in the present exemplary embodiment as well, a more efficient layout is realized by arranging the FD 106 between the columns.

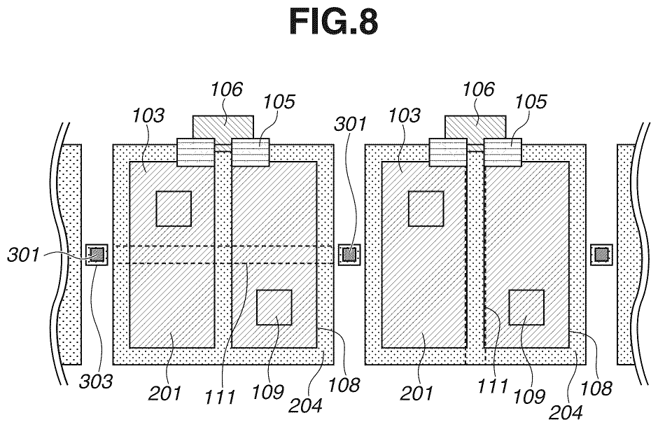

A third exemplary embodiment of the disclosure will be described with reference to FIG. 8.

In the photoelectric conversion apparatuses according to the first and the second exemplary embodiments, the well contact 301 and the first photoelectric conversion unit 103 are arranged in a continuous semiconductor region in a planar view. In other words, no separation structure is provided between the well contact 301 and the first photoelectric conversion unit 103.

In a photoelectric conversion apparatus according to the third exemplary embodiment, a semiconductor region in which the first photoelectric conversion unit 103 and the second photoelectric conversion unit 104 are arranged and a semiconductor region in which the well contact 301 is arranged are separated by a separation structure 303. Examples of the separation structure 303 include a separation structure that uses an insulating layer, such as local oxidation of silicon (LOCOS) and shallow trench isolation (STI). By arranging the separation structure 303 including an insulating layer surrounding the well contact 301, between the first photoelectric conversion unit 103 and the second photoelectric conversion unit 104, and the well contact 301, it is possible to prevent the dark current generated in the well contact 301 from flowing into the photoelectric conversion unit 103.

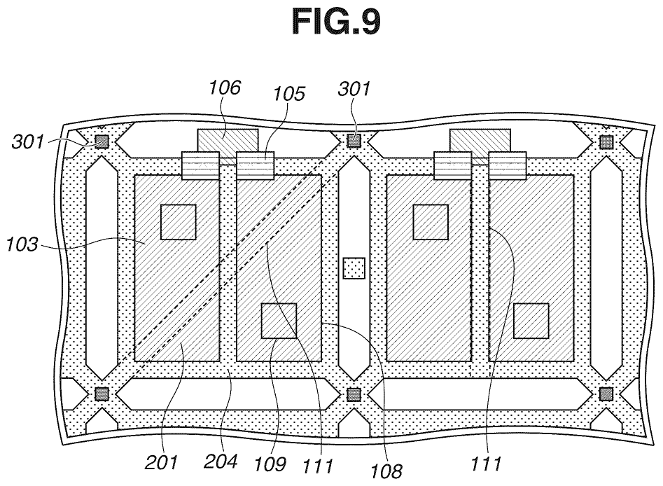

A fourth exemplary embodiment of the disclosure will be described with reference to FIG. 9.

As illustrated in FIG. 9, the present exemplary embodiment differs from the first to third exemplary embodiments in that the first photoelectric conversion unit 103 and the second photoelectric conversion unit 104 included in a pixel are arranged at a tilt angle of 45° in an array direction of a plurality of pixels.

Because a direction in which phase difference detection can be performed is determined based on the arrangement direction (array direction) of the rear surface side N-type regions 107, by arranging pixels each including a pair of photoelectric conversion units with a 45° arrangement illustrated in FIG. 9 in the photoelectric conversion apparatus together with the pixels each including the pair of photoelectric conversion units with a 0° arrangement according to the first exemplary embodiment and the pixels each including the pair of photoelectric conversion units with a 90° arrangement, for example, high-speed and highly-accurate AF on a larger number of subjects is implemented.

In the present exemplary embodiment as well, by arranging the well contact 301 on an extended line of the first separation portion 111, more stable potential supply is implemented, and a dark current is suppressed. By employing a structure in which the well contact 301 is arranged between pixel columns in a case where the FD 106 is arranged between pixel rows, which is not illustrated in FIG. 9, a more efficient layout arrangement is realized.

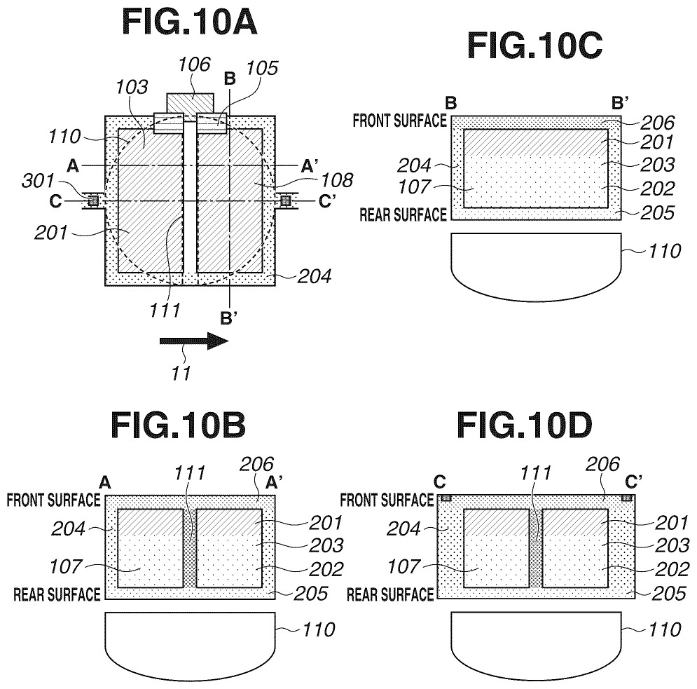

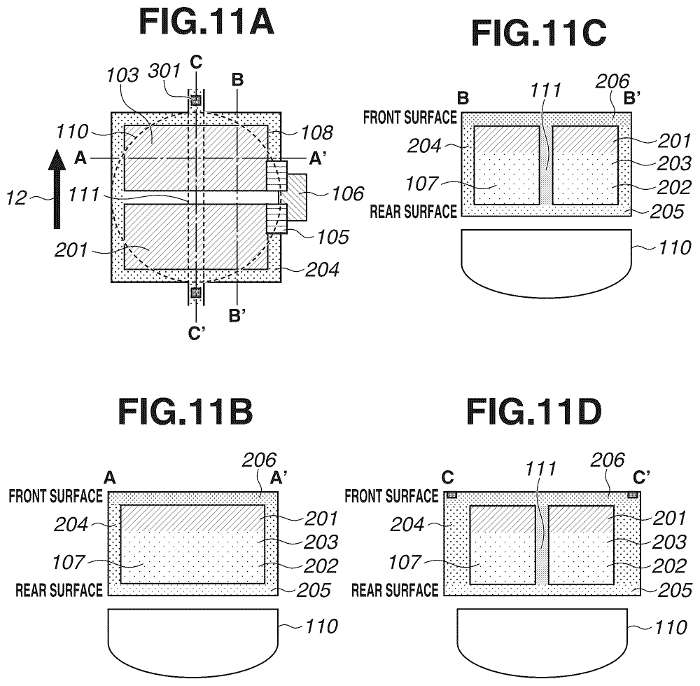

A fifth exemplary embodiment of the disclosure will be described with reference to FIGS. 10A, 10B, 10C, 10D, 11A, 11B, 11C, and 11D. In contrast to the first to fourth exemplary embodiments, in the present exemplary embodiment, arrangement directions of the front surface side N-type regions 108 and the rear surface side N-type regions 107 are the same with regard to a plurality of photoelectric conversion units 103 arranged in a pixel.

By arranging a pixel different in arrangement directions of the front surface side N-type regions 108 and the rear surface side N-type regions 107 from other pixels in the photoelectric conversion apparatus together with the other pixels, it is possible to change the phase difference detection direction while uniformizing the structure on the front surface side for each pixel. On the other hand, by forming the front surface side N-type region 108 and the rear surface side N-type region 107 in the same direction, it is possible to form a pixel by an easier process.

FIGS. 10A, 10B, 10C, and 10D illustrate a pixel in which the first photoelectric conversion unit 103 and the second photoelectric conversion unit 104 are arranged in the direction 11 (row direction) in which phase difference detection can be easily performed on a subject with vertical stripe contrast. FIGS. 11A, 11B, 11C, and 11D illustrate a pixel in which the first photoelectric conversion unit 103 and the second photoelectric conversion unit 104 are arranged in the direction 12 (column direction) in which the phase difference detection can be easily performed on a subject with horizontal stripe contrast. By arranging the pixel illustrated in FIGS. 10A, 10B, FIG. 10C, and 10D and the pixel illustrated in FIGS. 11A, 11B, 11C, and 11D in a pixel array, the phase difference detection in a plurality of directions becomes easier.

In such a pixel configuration as well, a more efficient layout arrangement is realized by arranging the FD 106 between pixel rows and arranging the well contact 301 between pixel columns.

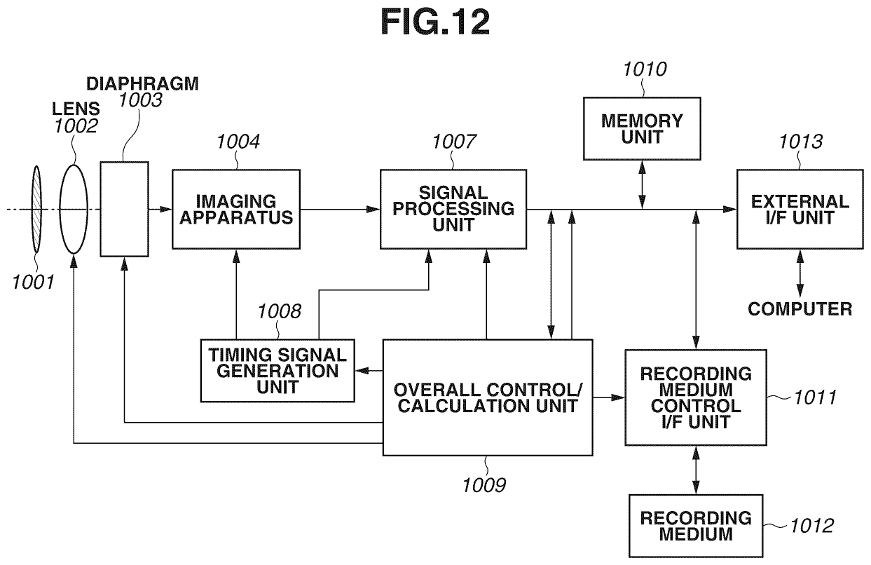

A photoelectric conversion system according to a sixth exemplary embodiment will be described with reference to FIG. 12. FIG. 12 is a block diagram schematically illustrating a configuration of a photoelectric conversion system according to the present exemplary embodiment.

The photoelectric conversion apparatuses according to the above-described first to fifth exemplary embodiments can be applied to various kinds of photoelectric conversion system. Examples of the photoelectric conversion system to which the photoelectric conversion apparatus can be applied include a digital still camera, a digital camcorder, a monitoring camera, a copier, a facsimile, a mobile phone, an in-vehicle camera, and an observation satellite. A camera module including an optical system, such as a lens, and an imaging apparatus is also included in the photoelectric conversion system. As an example of the photoelectric conversion system, FIG. 12 exemplarily illustrates a block diagram of a digital still camera.

The photoelectric conversion system exemplified in FIG. 12 includes an imaging apparatus 1004 that is an example of the photoelectric conversion apparatus, and a lens 1002 that forms an optical image of a subject on the imaging apparatus 1004. The photoelectric conversion system further includes a diaphragm 1003 for varying an amount of light passing through the lens 1002, and a barrier 1001 for protecting the lens 1002. The lens 1002 and the diaphragm 1003 serve as an optical system that condenses light onto the imaging apparatus 1004. The imaging apparatus 1004 is the photoelectric conversion apparatus (imaging apparatus) according to any of the above-described exemplary embodiments, and converts an optical image formed by the lens 1002 into an electric signal.

The photoelectric conversion system further includes a signal processing unit 1007 that is an image generation unit that generates an image by processing an output signal output from the imaging apparatus 1004. The signal processing unit 1007 performs an operation of outputting image data after performing various types of correction and compression as necessary. The signal processing unit 1007 may be formed on a semiconductor substrate on which the imaging apparatus 1004 is disposed, or may be formed on a semiconductor substrate different from that of the imaging apparatus 1004. Alternatively, the imaging apparatus 1004 and the signal processing unit 1007 may be formed on the same semiconductor substrate.

The photoelectric conversion system further includes a memory unit 1010 for temporarily storing image data, and an external interface unit (external I/F unit) 1013 for communicating with an external computer or the like. The photoelectric conversion system further includes a recording medium 1012, such as a semiconductor memory, for recording or reading captured image data, and a recording medium control interface unit (recording medium control I/F unit) 1011 for performing recording onto or reading from the recording medium 1012. The recording medium 1012 may be built into the photoelectric conversion system, or may be detachably attached to the photoelectric conversion system.

The photoelectric conversion system further includes an overall control/calculation unit 1009 that controls various types of calculation and the entire digital still camera, and a timing signal generation unit 1008 that outputs various timing signals to the imaging apparatus 1004 and the signal processing unit 1007. The timing signals may be input from the outside. The photoelectric conversion system is to include at least the imaging apparatus 1004 and the signal processing unit 1007 that processes an output signal output from the imaging apparatus 1004.

The imaging apparatus 1004 outputs an imaging signal to the signal processing unit 1007. The signal processing unit 1007 outputs image data after performing predetermined signal processing on the imaging signal output from the imaging apparatus 1004. The signal processing unit 1007 generates an image using the imaging signal.

In this manner, in the present exemplary embodiment, a photoelectric conversion system to which the photoelectric conversion apparatus (imaging apparatus) according to any of the above-described exemplary embodiments is applied can be realized.

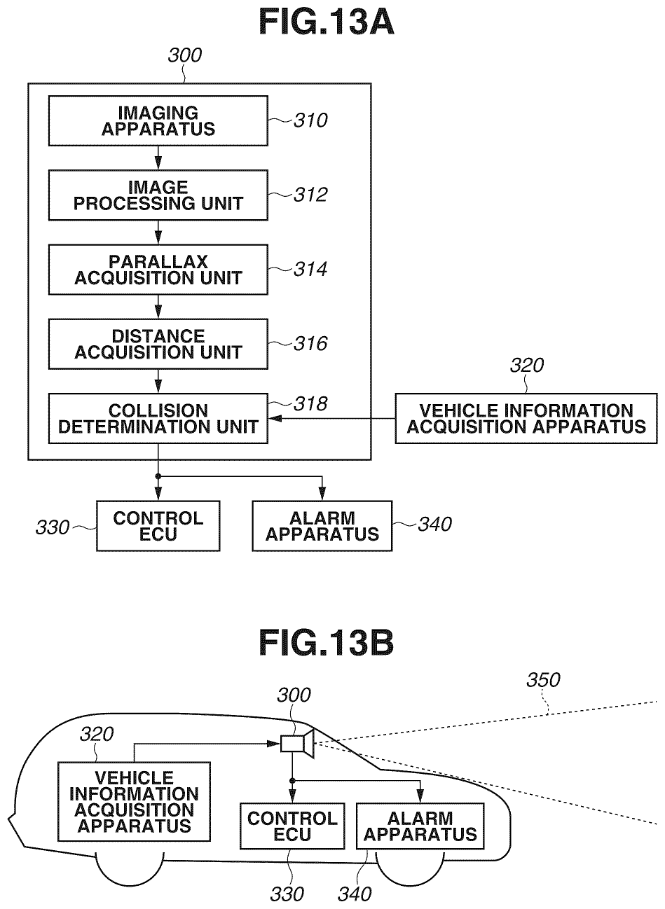

A photoelectric conversion system and a movable body according to a seventh exemplary embodiment will be described with reference to FIGS. 13A and 13B. FIGS. 13A and 13B are diagrams illustrating configurations of the photoelectric conversion system and the movable body according to the present exemplary embodiment.

FIG. 13A illustrates an example of a photoelectric conversion system related to an in-vehicle camera. A photoelectric conversion system 300 includes an imaging apparatus 310. The imaging apparatus 310 is the photoelectric conversion apparatus (imaging apparatus) according to any of the above-described exemplary embodiments. The photoelectric conversion system 300 includes an image processing unit 312 that performs image processing on a plurality of pieces of image data acquired by the imaging apparatus 310, and a parallax acquisition unit 314 that calculates parallax (phase difference between parallax images) from the plurality of pieces of image data acquired by the photoelectric conversion system 300. The photoelectric conversion system 300 further includes a distance acquisition unit 316 that calculates a distance to a target object based on the calculated parallax, and a collision determination unit 318 that determines whether a collision is likely to occur based on the calculated distance. In the present exemplary embodiment, the parallax acquisition unit 314 and the distance acquisition unit 316 are examples of a distance information acquisition unit that acquires distance information regarding a distance to a target object. More specifically, the distance information is information regarding parallax, a defocus amount, and a distance to the target object. The collision determination unit 318 may determine a collision likelihood using any of the pieces of distance information. The distance information acquisition unit may be implemented by dedicatedly-designed hardware, or may be implemented by a software module. Alternatively, the distance information acquisition unit may be implemented by a field programmable gate array (FPGA), an application specific integrated circuit (ASIC), or the like or may be implemented by a combination thereof.

The photoelectric conversion system 300 is connected with a vehicle information acquisition apparatus 320, and can acquire vehicle information, such as a vehicle speed, a yaw rate, and a steering angle. In addition, a control electronic control unit (ECU) 330 is connected to the photoelectric conversion system 300. The ECU 330 is a control apparatus that outputs a control signal for generating braking force to a vehicle based on a determination result obtained by the collision determination unit 318. The photoelectric conversion system 300 is also connected with an alarm apparatus 340 that issues an alarm to a driver based on a determination result obtained by the collision determination unit 318. For example, in a case where the determination result obtained by the collision determination unit 318 indicates high collision likelihood, the control ECU 330 performs vehicle control to avoid a collision or reduce damages by braking, releasing an accelerator, or suppressing engine output. The alarm apparatus 340 issues an alarm to the driver by sounding an alarm such as sound, displaying warning information on a screen of a car navigation system, or vibrating a seatbelt or a steering wheel.

In the present exemplary embodiment, the photoelectric conversion system 300 captures an image of surroundings of the vehicle, such as the front side or the rear side, for example. FIG. 13B illustrates the photoelectric conversion system 300 in a case where an image of a vehicle front side (imaging range 350) is capture. The vehicle information acquisition apparatus 320 issues an instruction to the photoelectric conversion system 300 or the imaging apparatus 310. With this configuration, accuracy of distance measurement can be further enhanced.

The above description has been given of an example in which control is performed in such a manner as not to collide with another vehicle. The photoelectric conversion system 300 can also be applied to the control to perform autonomous operation by following another vehicle, or the control for performing autonomous operation in such a manner as not to deviate from a lane. Furthermore, the photoelectric conversion system 300 can be applied to a movable body (moving apparatus), such as a vessel, an aircraft, or an industrial robot, aside from a vehicle such as an automobile. The movable body includes either one or both of a drive force generation unit that generates a driving force to be mainly used for the movement of the movable body, and a rotary member to be mainly used for the movement of the movable body. The drive force generation unit can be an engine, a motor, or the like. The rotary member can be a tire, a wheel, a screw of a ship, a propeller of a flight vehicle, or the like. Moreover, the photoelectric conversion system 300 can be applied to a device that extensively uses object recognition, such as an intelligent transport system (ITS), in addition to a movable body.

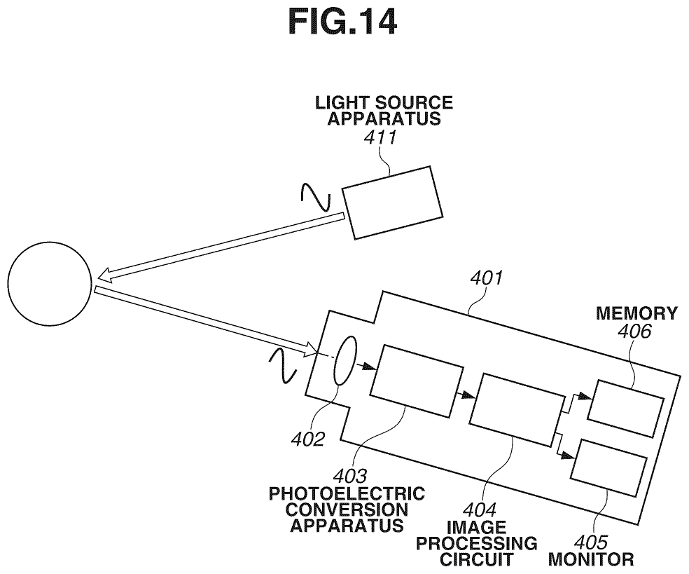

A photoelectric conversion system according to an eighth exemplary embodiment will be described with reference to FIG. 14. FIG. 14 is a block diagram illustrating a configuration example of a distance image sensor that is the photoelectric conversion system according to the present exemplary embodiment.

As illustrated in FIG. 14, a distance image sensor 401 includes an optical system 402, a photoelectric conversion apparatus 403, an image processing circuit 404, a monitor 405, and a memory 406. The distance image sensor 401 can acquire a distance image corresponding to a distance to a subject by receiving light (modulated light or pulse light) that has been emitted from a light source apparatus 411 toward the subject and reflected on a surface of the subject.

The optical system 402 includes one lens or a plurality of lenses, and forms an image on a light receiving surface (sensor portion) of the photoelectric conversion apparatus 403 by guiding image light (incident light) from the subject to the photoelectric conversion apparatus 403.

The photoelectric conversion apparatus described in each of the above exemplary embodiments is applied to the photoelectric conversion apparatus 403, and a distance signal indicating a distance obtained from a light receiving signal output from the photoelectric conversion apparatus 403 is supplied to the image processing circuit 404.

The image processing circuit 404 performs image processing of constructing a distance image based on the distance signal supplied from the photoelectric conversion apparatus 403. Then, the distance image (image data) obtained by the image processing is supplied to the monitor 405 and displayed thereon, or is supplied to the memory 406 and stored (recorded) therein.

By the above-described photoelectric conversion apparatus being applied to the distance image sensor 401, the distance image sensor 401 having the above-described configuration can acquire a more accurate distance image, for example, in accordance with improvement of characteristics of a pixel.

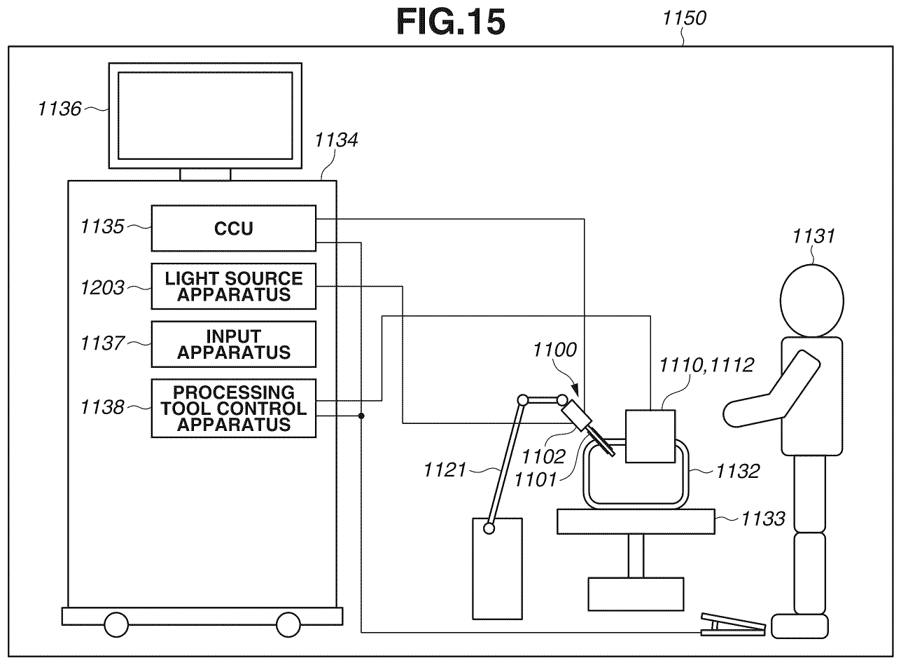

A photoelectric conversion system according to a ninth exemplary embodiment will be described with reference to FIG. 15. FIG. 15 is a diagram schematically illustrating an example of a configuration of an endoscopic operation system that is a photoelectric conversion system according to the present exemplary embodiment.

FIG. 15 illustrates a state in which an operator (doctor) 1131 is performing an operation on a patient 1132 lying on a patient bed 1133, using an endoscopic operation system 1150. As illustrated in FIG. 15, the endoscopic operation system 1150 includes an endoscope 1100, a surgical tool 1110, and a cart 1134 equipped with various apparatuses for an endoscopic operation.

The endoscope 1100 includes a lens barrel 1101 having a region to be inserted into a body cavity of the patient 1132 by a predetermined length from a distal end, and a camera head 1102 connected to a proximal end of the lens barrel 1101. In the example illustrated in FIG. 15, the endoscope 1100 formed as what is called a rigid scope including the rigid lens barrel 1101 is illustrated, but the endoscope 1100 may be formed as a flexible scope including what is called a flexible lens barrel.

An opening portion into which an objective lens is fitted is disposed at the distal end of the lens barrel 1101. A light source apparatus 1203 is connected to the endoscope 1100, and light generated by the light source apparatus 1203 is guided to the distal end of the lens barrel 1101 by a light guide extended inside the lens barrel 1101, and emitted toward an observation target in the body cavity of the patient 1132 via the objective lens. The endoscope 1100 may be a direct view endoscope, or may be an oblique view endoscope or a lateral view endoscope.

An optical system and a photoelectric conversion apparatus are provided inside the camera head 1102. Reflected light (observation light) from the observation target is condensed by the optical system on the photoelectric conversion apparatus. The observation light is photoelectrically converted by the photoelectric conversion apparatus, and an electric signal corresponding to the observation light, i.e., an image signal corresponding to an observed image, is generated. The photoelectric conversion apparatus (imaging apparatus) described in each of the above exemplary embodiments can be used as the photoelectric conversion apparatus. The image signal is transmitted to a camera control unit (CCU) 1135 as RAW data.

The CCU 1135 includes a central processing unit (CPU) or a graphics processing unit (GPU), and comprehensively controls operations of the endoscope 1100 and a display device 1136. Furthermore, the CCU 1135 receives an image signal from the camera head 1102, and performs various types of image processing for displaying an image based on the image signal, such as development processing (demosaic processing), on the image signal.

Based on the control by the CCU 1135, the display device 1136 displays the image based on the image signal on which image processing has been performed by the CCU 1135.

The light source apparatus 1203 includes a light source, such as a light emitting diode (LED), and supplies irradiation light for capturing an image of an operative site or the like to the endoscope 1100.

An input apparatus 1137 is an input interface for the endoscopic operation system 1150. A user can input various types of information and instructions to the endoscopic operation system 1150 via the input apparatus 1137.

A processing tool control apparatus 1138 controls driving of an energy processing tool 1112 for cauterizing or cutting a tissue, or sealing a blood vessel.

The light source apparatus 1203 that supplies irradiation light for capturing an image of an operative site to the endoscope 1100 can include, for example, an LED, a laser light source, or a white light source including a combination of these. In a case where the white light source includes a combination of red, green, and blue (RGB) laser light sources, because output intensity and an output timing of each color (each wavelength) can be controlled with high accuracy, white balance of a captured image can be adjusted in the light source apparatus 1203. In this case, by emitting laser light from each of the RGB laser light sources to an observation target in a time division manner and controlling driving of an image sensor of the camera head 1102 in synchronization with an emission timing thereof, an image corresponding to each of RGB can also be captured in the time division manner. By using the method, a color image can be obtained without providing a color filter in the image sensor.

Driving of the light source apparatus 1203 may be controlled in such a manner as to change the intensity of light to be output every predetermined time. By acquiring images in the time division manner by controlling the driving of the image sensor of the camera head 1102 in synchronization with a change timing of the light intensity, and combining the acquired images, it is possible to generate a high dynamic range image without underexposure and overexposure.

The light source apparatus 1203 may be configured to supply light in a predetermined wavelength band suitable for special light observation. In the special light observation, for example, wavelength dependency of light absorption in body tissues is used. Specifically, by emitting light in a narrow band as compared with irradiation light (i.e., white light) in normal observation, an image of a predetermined tissue, such as a blood vessel of a superficial portion of a mucous membrane, is captured with high contrast.

Alternatively, in the special light observation, fluorescent observation in which an image of fluorescence generated by emitting excitation light is obtained may be performed. In the fluorescent observation, fluorescence from a body tissue can be observed by emitting excitation light to the body tissue, or a fluorescent image can be obtained by locally injecting a reagent, such as indocyanine green (ICG), into a body tissue and emitting excitation light suitable for a fluorescence wavelength of the reagent, to the body tissue. The light source apparatus 1203 can be configured to supply narrow-band light and/or excitation light suitable for such special light observation.

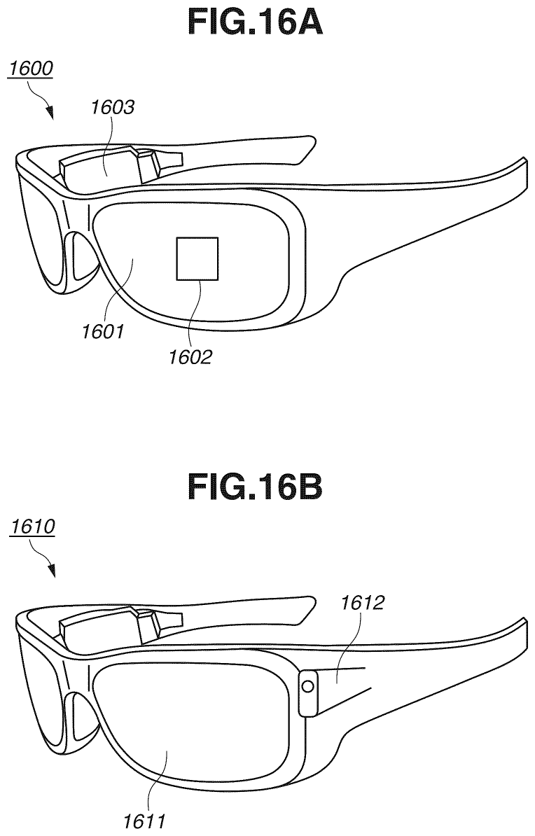

A photoelectric conversion system according to a tenth exemplary embodiment will be described with reference to FIGS. 16A and 16B. FIG. 16A is a diagram illustrating glasses 1600 (smart glasses) that are a photoelectric conversion system according to the present exemplary embodiment. The glasses 1600 include a photoelectric conversion apparatus 1602. The photoelectric conversion apparatus 1602 is the photoelectric conversion apparatus (imaging apparatus) described in each of the above exemplary embodiments. A display device including a light emission device, such as an organic light emitting diode (OLED) or an LED, may be arranged on the rear surface side of a lens 1601. The number of photoelectric conversion apparatuses 1602 may be one or two or more. A plurality of types of photoelectric conversion apparatuses may be used in combination. An arrangement position of the photoelectric conversion apparatus 1602 is not limited to the position illustrated in FIG. 16A.

The glasses 1600 further include a control apparatus 1603. The control apparatus 1603 functions as a power supply that supplies power to the photoelectric conversion apparatus 1602 and the above-described display device. The control apparatus 1603 controls operations of the photoelectric conversion apparatus 1602 and the display device. In the lens 1601, an optical system for condensing light on the photoelectric conversion apparatus 1602 is formed.

FIG. 16B illustrates glasses 1610 (smart glasses) according to one application example. The glasses 1610 include a control apparatus 1612, and the control apparatus 1612 is equipped with a photoelectric conversion apparatus equivalent to the photoelectric conversion apparatus 1602, and a display device. In a lens 1611, an optical system for projecting light emitted from the photoelectric conversion apparatus and the display device in the control apparatus 1612 is formed, and an image is projected onto the lens 1611. The control apparatus 1612 functions as a power supply that supplies power to the photoelectric conversion apparatus and the display device and controls operations of the photoelectric conversion apparatus and the display device. The control apparatus may include a line-of-sight detection unit that detects a line of sight of a wearer. Infrared light may be used to detect a line of sight. An infrared light emission unit emits infrared light to an eyeball of a user looking at a displayed image. An imaging unit including a light receiving element detects reflected light of the emitted infrared light that has been reflected from the eyeball. A captured image of the eyeball is thereby obtained. By including a reduction unit that reduces light from the infrared light emission unit to a display unit in a planar view, a deterioration in image quality is reduced.

From the captured image of the eyeball obtained by image capturing using infrared light, the line of sight of the user toward a displayed image is detected. Any known method can be applied to line-of-sight detection that uses a captured image of an eyeball. As an example, a line-of-sight detection method based on a Purkinje image obtained by reflection of irradiation light on a cornea can be used.

More specifically, line-of-sight detection processing based on the pupil center corneal reflection is performed. By calculating a line-of-sight vector representing a direction (rotational angle) of an eyeball, based on an image of a pupil and a Purkinje image that are included in a captured image of the eyeball, using the pupil center corneal reflection, the line-of-sight of the user is detected.

The display device according to the present exemplary embodiment includes the photoelectric conversion apparatus including a light receiving element, and a displayed image of the display device may be controlled based on line-of-sight information of the user from the photoelectric conversion apparatus.

Specifically, in the display device, a first field-of-view region viewed by the user, and a second field-of-view region other than the first field-of-view region are determined based on the line-of-sight information. The first field-of-view region and the second field-of-view region may be determined by a control apparatus of the display device, or the first field-of-view region and the second field-of-view region determined by an external control apparatus may be received. In a display region of the display device, display resolution of the first field-of-view region may be controlled to be higher than display resolution of the second field-of-view region. In other word, resolution of the second field-of-view region may be made lower than resolution of the first field-of-view region.

The display region includes a first display region and a second display region different from the first display region. Based on the line-of-sight information, a region with high priority may be determined from the first display region and the second display region. The first display region and the second display region may be determined by a control apparatus of the display device, or the first display region and the second display region determined by an external control apparatus may be received. Resolution of the region with high priority may be controlled to be higher than resolution of a region other than the region with high priority. In other words, resolution of a region with relatively low priority may be set to be low.

Artificial intelligence (AI) may be used to determine the first field-of-view region and the region with high priority. The AI may be a model configured to estimate an angle of a line-of-sight and a distance to a target existing at the end of the line-of-sight from an image of an eyeball using supervised data including an image of the eyeball and a direction in which the eyeball in the image actually gives a gaze. An AI program may be included in the display device, may be included in the photoelectric conversion apparatus, or may be included in an external apparatus. In a case where the external apparatus includes the AI program, the AI program is transmitted to the display device via a means of communication.

In a case where display control is performed based on the line-of-sight detection, the present exemplary embodiment can be applied to smart glasses further including a photoelectric conversion apparatus that captures an image of the outside. The smart glasses can display external information obtained by image capturing, in real time.

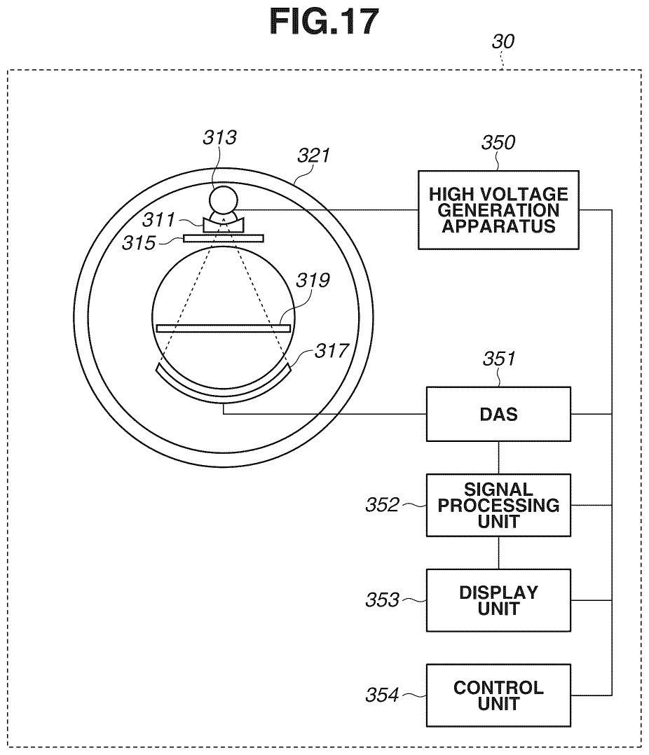

FIG. 17 is a block diagram of an X-ray computed tomography (CT) apparatus according to an eleventh exemplary embodiment. As described above, any of the photoelectric conversion apparatuses according to the first to fifth exemplary embodiments can be applied to a detector of the X-ray CT apparatus. An X-ray CT apparatus 30 according to the present exemplary embodiment includes an X-ray generation unit 313, a wedge 311, a collimator 315, an X-ray detection unit 317, a top board 319, a rotation frame 321, and a high voltage generation apparatus 350.

The X-ray CT apparatus 30 further includes a data acquisition system (DAS) 351, a signal processing unit 352, a display unit 353, and a control unit 354.

The X-ray generation unit 313 includes a vacuum tube that generates X-rays, for example. A high voltage and a filament current from the high voltage generation apparatus 350 are supplied to the vacuum tube of the X-ray generation unit 313. By thermal electrons being emitted from a negative pole (filament) toward a positive pole (target), X-rays are generated.

The wedge 311 is a filter that adjusts an X-ray dosage emitted from the X-ray generation unit 313. The wedge 311 attenuates the X-ray dosage so that X-rays emitted from the X-ray generation unit 313 toward a subject have a predetermined distribution. The collimator 315 includes a lead plate that narrows down an emission range of X-rays that have passed through the wedge 311. The X-rays generated by the X-ray generation unit 313 are formed into a cone-beam shape via the collimator 315 and emitted toward the subject on the top board 319.

The X-ray detection unit 317 includes any of the photoelectric conversion apparatuses according to the above-described second and third exemplary embodiments. The X-ray detection unit 317 detects X-rays that have been generated by the X-ray generation unit 313 and passed through the subject, and outputs a signal corresponding to an X-ray dosage to the DAS 351.

The rotation frame 321 has an annular shape and is configured to be rotatable. Inside the rotation frame 321, the X-ray generation unit 313 (wedge 311, collimator 315) and the X-ray detection unit 317 are arranged to face each other. The X-ray generation unit 313 and the X-ray detection unit 317 can rotate together with the rotation frame 321.

The high voltage generation apparatus 350 includes a booster circuit and outputs a high voltage to the X-ray generation unit 313. The DAS 351 includes an amplification circuit and an analog-to-digital (A/D) conversion circuit, and outputs a signal from the X-ray detection unit 317 to the signal processing unit 352 as digital data.

The signal processing unit 352 includes a central processing unit (CPU), a read only memory (ROM), and a random access memory (RAM) and can execute image processing on digital data. The display unit 353 includes a flat-panel display device, and can display an X-ray image. The control unit 354 includes a CPU, a ROM, and a RAM, and controls operations of the entire X-ray CT apparatus 30.

The exemplary embodiments described above can be appropriately changed without departing from the technical concept. The disclosure in the present specification is not limited to matters described herein, and includes all matters that can be identified from the present specification and the drawings accompanying the present specification. The disclosure in the present specification includes a complementary set of individual concepts described in the present specification. More specifically, if “A is larger than B” is described in the present specification, even if a description of “A is not larger than B” is omitted, the present specification is assumed to disclose the description of “A is not larger than B”. This is because, in a case where “A is larger than B” is described, a case where “A is not larger than B” is assumed to be considered.

According to the exemplary embodiments of the disclosure, it is possible to realize the photoelectric conversion apparatus that takes into account an influence of the well contact exerted on pixel characteristics.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-200344, filed Nov. 28, 2023, which is hereby incorporated by reference herein in its entirety.

What is claimed is:

1. An apparatus comprising:
a plurality of pixels arranged in an array,
wherein each of the plurality of pixels includes a plurality of conversion units that share a microlens,
wherein the plurality of conversion units of a first pixel of the plurality of pixels is separated in a first direction,
wherein the plurality of conversion units of a second pixel of the plurality of pixels is separated in a second direction,
wherein a floating diffusion is arranged in one of a position between columns and a position between rows of the conversion units included in the plurality of pixels, and
wherein a well contact is arranged in the other of the position between columns and the position between rows of the conversion units included in the plurality of pixels.

2. The apparatus according to claim 1, wherein the well contact is arranged between two transistors of a same type.

3. The apparatus according to claim 2,
wherein the first pixel includes a first selection transistor,
wherein the second pixel includes a second selection transistor, and
wherein the well contact is arranged between the first selection transistor and the second selection transistor.

4. The apparatus according to claim 1, wherein, in a case where two line segments extending in the first direction are arranged in such a manner that an area of the first pixel is equally divided into three, the well contact is arranged in a region sandwiched between the two line segments.

5. The apparatus according to claim 1, wherein a center of the well contact is arranged in a region within ±1 μm from an extended line obtained by extending a separation portion in a longer side direction of the separation portion, in a direction orthogonal to the extended line in a planar view.

6. The apparatus according to claim 1, wherein, when a line segment extending in a longer side direction of a separation portion that passes through a center of the separation portion is assumed, the line segment passes through the well contact in a planar view.

7. The apparatus according to claim 1, wherein the first direction and the second direction are orthogonal to each other.

8. The apparatus according to claim 1,
wherein the first direction is a column direction of an array in which the plurality of pixels is arranged, and
wherein the second direction is a row direction of the array in which the plurality of pixels is arranged.

9. The apparatus according to claim 1, further comprising a separation portion separating the plurality of conversion units of the first pixel in the first direction, and a separation portion separating the plurality of conversion units of the second pixel in the second direction,
wherein, in the first pixel and the second pixel, the plurality of conversion units and the separation portions differ in a conductivity type of an impurity.

10. The apparatus according to claim 1, further comprising a separation portion separating the plurality of conversion units of the first pixel in the first direction, and a separation portion separating the plurality of conversion units of the second pixel in the second direction,
wherein, in the first pixel and the second pixel, the separation portions each have a trench structure.

11. The apparatus according to claim 1, wherein a separation portion is arranged between a region in which the well contact is arranged and the conversion unit of the first pixel.

12. The apparatus according to claim 1, wherein a region in which the well contact is arranged and the conversion unit of the first pixel constitute a continuous semiconductor region.

13. The apparatus according to claim 1, wherein the well contact is arranged in a region shallower than the conversion unit.

14. A system comprising:
the apparatus according to claim 1; and
a signal processing unit configured to generate an image using a signal output by the apparatus.

15. The system according to claim 14, wherein the well contact is arranged between two transistors of a same type.

16. The system according to claim 14, wherein, in a case where two line segments extending in the first direction are arranged in such a manner that an area of the first pixel is equally divided into three, the well contact is arranged in a region sandwiched between the two line segments.

17. The system according to claim 14, wherein a center of the well contact is arranged in a region within ±1 μm from an extended line obtained by extending a separation portion in a longer side direction of the separation portion, in a direction orthogonal to the extended line in a planar view.

18. The system according to claim 14, wherein, when a line segment extending in a longer side direction of a separation portion that passes through a center of the separation portion is assumed, the line segment passes through the well contact in a planar view.

19. The system according to claim 14, wherein the first direction and the second direction are orthogonal to each other.

20. A movable body including the apparatus according to claim 1, the movable body comprising:
a control unit configured to control a movement of the movable body using a signal output by the apparatus.
